(19) United States
(12) Patent Application Publication
(10) Pub. No.: US 2001/0050331 A1
(43) Pub. Date: Dec. 13, 2001

(54) Staggered bilinear sensor

(76) Inventors: Benjamin P. Yung, Cupertino, CA (US); Jonathan D. Isom, Austin, TX (US)

Correspondence Address: SIMON, FAKHOURY, TANGALOS, FRANTZ & GALASSO, PLC., P.O. Box 26503, Austin, TX, 78755-0503, US

(21) Appl. No.: 09/752,156

(22) Filed: Dec. 29, 2000

Related U.S. Application Data
(60) Provisional application No. 60/173,651, filed on Dec. 30, 1999.

(51) Int. Cl. H01L 27/00

(52) U.S. Cl. 250/208.1

(57) ABSTRACT

The present invention provides an image sensor that includes a first sensor row and a second sensor row. The first sensor row is formed by two or more imaging elements separated from each other by a non-imaging material. Similarly, the second sensor row is formed by two or more imaging elements separated from each other by the non-imaging material. The imaging elements in the second sensor row are separated and offset from the imaging elements in the first sensor row by the non-imaging material.

### CROSS REFERENCE TO RELATED APPLICATIONS

This application claims the benefit of U.S. Provisional Patent Application Serial No. 60/173,651 filed Dec. 30, 1999 entitled “STAGGERED BILINEAR SENSOR,” of common assignee herewith.

### FIELD OF THE INVENTION

The present invention relates generally to scanned image sensors, and more particularly to a staggered bilinear sensor.

### BACKGROUND OF THE INVENTION

Image sensors are used in copiers, scanners, digital cameras, and security devices. Without limiting the scope of the present invention the present invention is described in connection with digital film processing systems. Digital film processing systems generally utilize infrared or near infrared electromagnetic energy, i.e. light, to digitize film as it is developing. In particular, digital film processing systems operate by identifying the density of silver grains in the layers of the developing film. The density of silver grains are then correlated to colors to produce a digital image of the image on the film.

Typical image sensors are formed by an array of imaging elements wherein each imaging element corresponds to a pixel or picture element in a digital image. When an image sensor is working in the near infrared spectra, the image sensor suffers from a degraded ability to resolve image detail because near infrared photons generate electrons deeper in the silicon than a normal imaging element's depletion region, which is used to capture the electrons generated by the photons. Once these electrons are generated outside the depletion region, they can diffuse or wander into neighboring imaging elements and cause the captured image of a point to be smeared across several pixels.

The diffusion of electrons normally generated outside the depletion region can be prevented by increasing the depth of the depletion region so that electrons generated deep within the imaging element's epitaxial layer can be captured in the correct imaging element. Moreover, diffusion can be limited by causing the electrons generated past the imaging element's depletion region to recombine in the substrate, which causes the electrons to disappear, instead of allowing them to diffuse to neighboring imaging elements. But allowing the electrons to recombine in the substrate degrades image sensor efficiency because some percentage of the electrons generated below the image element's depletion region would have ended up in the correct imaging element and as a result, would not have degraded the sensor's modulation transfer function (“MTF”) (a measure of the extent to which an image sensor, lens or film can reproduce detail in an image). Moreover, it is more difficult to manufacture sensors with deep depletion regions, which results in reduced sensor yield due to increased defect rates. The use of dep depletion regions also hurts noise performance because of increased dark current levels.

In addition, typical image sensors are inherently under sampled, which means that the image sensor captures image detail at higher spatial frequencies than are reproduced in the sensor's final output image. This higher spatial frequency image detail is aliased, or represented as image detail at a lower spatial frequency. As a result, the high frequency noise apparent in the sensor's final output image is significantly increased over that actually present in the image being scanned whenever the image being scanned contains noise that has spectral content above the image sensor's Nyquist frequency (the upper limit for frequency content that may be reproduced in the sampled image).

Conventional methods for correcting the aliasing problem include using a higher number of smaller imaging elements in the image sensor. Using smaller imaging elements causes the sensor's Nyquist frequency to be increased so that a smaller portion of the high frequency noise contained in the image being scanned is misrepresented as low frequency noise in the final output image. Using smaller imaging elements to sample at a higher spatial frequency, however, hurts sensitivity because the imaging element's area goes down as the square of the imaging element's length. Accordingly, fitting twice as many imaging elements in a given length decreases the imaging element's area by four times, which means that the sensitivity of the imaging elements is decreased by a factor of four. This decreased sensitivity can make the electronic noise present in the output image worse in applications where the lens f-stop or illuminator brightness cannot be adjusted to increase the light level on the image sensor.

As a result, there is a need for an image sensor that reduces high frequency noise in the output image without significant loss of sensitivity, and improves performance in the near infrared spectra without using sensors having deep depletion regions.

### SUMMARY OF THE INVENTION

In one embodiment, the present invention provides an image sensor that includes a first sensor row and a second sensor row. In this embodiment the first sensor row is formed by two or more imaging elements separated from each other by a non-imaging material. Similarly, the second sensor row is formed by two or more imaging elements separated from each other by the non-imaging material. The imaging elements in the second sensor row are separated and offset from the imaging elements in the first sensor row by the non-imaging material.

In another embodiment, the present invention provides an image sensor that includes a first sensor row and a second sensor row. In this embodiment, the first sensor row is formed by two or more imaging elements separated from each other by a non-imaging material having a width of approximately one-half the width of the imaging element. The non-imaging material is used to reduce diffusion between neighboring imaging elements. Similarly, the second sensor row is formed by two or more imaging elements separated from each other by the non-imaging material having a width of approximately on-half the width of the imaging element. The imaging elements in the first sensor row are also separated from the neighboring imaging elements in the second sensor row by the non-imaging material having a width of approximately one-half the width of the imaging element. Moreover, the imaging elements in the first sensor row are offset from the imaging elements in the second sensor row by a distance of approximately one-half times the sum of the width of the imaging element and the non-imaging material between adjacent imaging elements.

In yet another embodiment, the present invention provides an image sensor that includes a first sensor row, a second sensor row, a first readout register, a second readout register, a delay circuit and an adder circuit. The first sensor row is formed by two or more imaging elements separated from each other by a non-imaging material operable to reduce diffusion between neighboring imaging elements. Similarly, the second sensor row is formed by two or more imaging elements separated from each other by the non-imaging material. The imaging elements in the second sensor row are separated and offset from the imaging elements in the first sensor row by the non-imaging material. The first readout register is coupled to the first sensor row and operable to read a first image signal from each of the imaging elements in the first sensor row and converting the first image signals into a first digital image. Similarly, the second readout register is coupled to the second sensor row and operable to read a second image signal from each of the imaging elements in the second sensor row and converting the second image signals into a second digital image. The delay circuit is coupled to the second readout register to delay the second digital image for a time period corresponding to the distance between the first sensor row and the second sensor row. The adder circuit is coupled to the first readout register and the delay circuit to produce a digital output image by adding the first digital image to the second digital image.

Other features and advantages of the present invention shall be apparent to those of ordinary skill in the art upon reference to the following detailed description taken in conjunction with the accompanying drawings.

### BRIEF DESCRIPTION OF THE DRAWINGS

The above and further advantages of the invention may be better understood by referring to the following description in conjunction with the accompanying drawings in which corresponding numerals in the different figures refer to corresponding parts in which:

FIG. 1 is a block diagram illustrating a scanning device in accordance with the present invention;

FIG. 2 is an illustration of a duplex film processing system in accordance with the present invention;

FIG. 3 shows a configuration of imaging elements in accordance with the present invention;

FIG. 4 shows a configuration of imaging elements in accordance with the present invention;

FIG. 5 shows a configuration of imaging elements in accordance with the present invention;

FIG. 6 is a block diagram of a image sensor in accordance with the present invention; and

FIG. 7 is a block diagram of a image processing circuit in accordance with the present invention.

### DETAILED DESCRIPTION OF A PREFERRED EMBODIMENT OF THE INVENTION

While the making and using of various embodiments of the present invention are discussed herein in terms of a digital film processing system, it should be appreciated that the present invention provides many applicable inventive concepts which can be embodied in a wide variety of specific contexts. For example, the present invention can be used in copiers, digital cameras and security devices. The specific embodiments discussed herein are merely illustrative of specific ways to make and use the invention and do not delimit the scope of the invention.

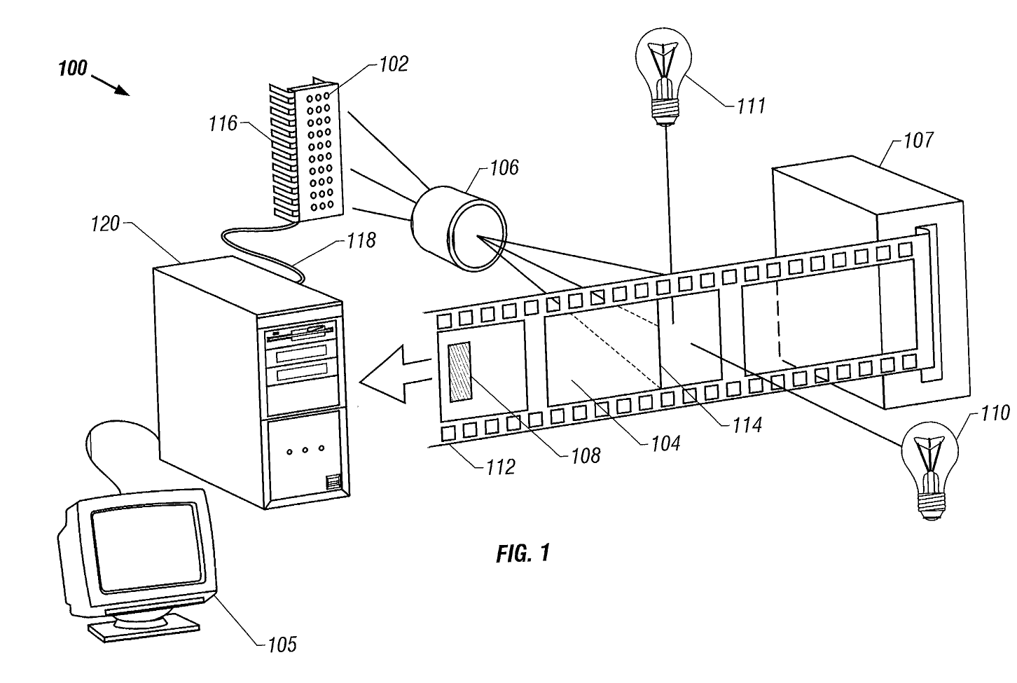

An improved imaging system 100 is shown in FIG. 1. Specifically, the imaging system 100 is illustrated as a digital film processing system. The imaging system 100 operates by converting electromagnetic radiation from a scene image 104 stored on a film 112 to an electronic (digital) representation of the image. The image being scanned is embodied in a photographic media, such as film. The electromagnetic radiation used to convert the image into a digitized representation is preferably infrared light or near infrared light.

The imaging system 100 generally includes a number of optic sensors 102. The optic sensors 102 measure the intensity of electromagnetic energy passing through or reflected by the film 112. The source of electromagnetic energy is typically a light source 110 which illuminated the film 112 containing the scene image 104. Radiation from the source 110 may be diffused or directed by additional optics such as filters (not shown) and one or more lenses 106 positioned near the sensors 102 and the film 114 in order to illuminate the image 104 more uniformly. Furthermore, more than one source may be used.

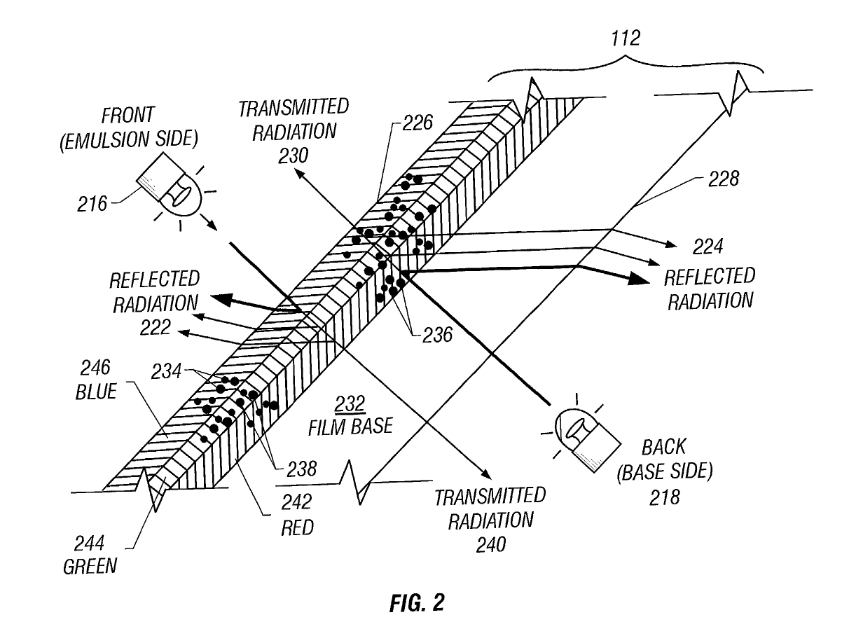

Source 110 is positioned on the side of the film 112 opposite the optic sensors 102. This placement results in sensors 102 detecting radiation emitted from source 110 as it passes through the image 104 on the film 112. Another radiation source 111 is shown placed on the same side of the film 112 as the sensors 102. When source 111 is activated, sensors 102 detect radiation reflected by the image 104. This process of using two sources positioned on opposite sides of the film 112 is described in more detail below in conjunction with FIG. 2.

The optic sensors 102 are generally geometrically positioned in arrays such that the electromagnetic energy striking each optical sensor 102 corresponds to a distinct location 114 in the images 104 and 108. Accordingly, each distinct location 114 in the scene image 104 corresponds to a distinct location, referred to as a picture element, or “pixel” for short, in the scanned, or digitized image 105. The image 104 on film 112 are usually sequentially moved, or scanned, across the optical sensor array 102. The optical sensors 102 are typically housed in a circuit package 116 that is electrically connected, such as by cable 118, to supporting electronics for computer data storage and processing, shown together as computer 120. Computer 120 may then process the digitized image 105. Alternatively, computer 120 may be replaced with a microprocessor and cable 118 replaced with an electrical circuit connection.

Optical sensors 102 may be manufactured from different materials and by different processes to detect electromagnetic radiation in varying parts and bandwidths of the electromagnetic spectrum. The optical sensor 102 includes a photodetector (not expressly shown) that produces an electrical signal proportional to the intensity of electromagnetic energy striking the photodetector. Accordingly, the photodetector measures the intensity of electromagnetic radiation attenuated by the image 104 on film 112.

Turning now to FIG. 2, a convention color film 220 is depicted. Duplex film scanning refers to using a front source 216 and a back source 218 to scan the film 112 with reflected radiation 222 from the front 226 and reflected radiation 224 from the back 228 of the film 112 and by transmitted radiation 230 and 240 that passes through layers of the film 112. The sources 216, 218 are generally monochromatic and preferable infrared. The respective scans, referred to herein as front, back, front-through and back-through, are further described below.

In FIG. 2, separate color levels are viewable within the film 112 during development of the red layer 242, green layer 244 and blue layer 246. Over a clear film bases 232 are three layers 242, 244, 246 sensitive separately to red, green and blue light, respectively. These layers are not physically the colors but rather, they are sensitive to these colors. In conventional color film development, the blue sensitive layer 246 would eventually develop a yellow dye, the green sensitive layer 244 a magenta dye, and the red sensitive layer 242 a cyan dye.

During development, layers 242,244, and 246 are opalescent. Dark silver grains 234 developing in the top layer 246, the blue source layer, are visible from the front 226 of the film, and slightly visible from the back 228 because of the bulk of the opalescent emulsion. Similarly, grains 236 in the bottom layer 242, but are much less visible from the front 226. Grains 238 in the middle layer 244, the green sensitive layer, are only slightly visible to reflected radiation 222, 224 from the front 226 or the back 228. However, they are visible along with those in the other layers by transmitted radiation 230 and 240. By sensing radiation reflected from the front 226 and the back 228 as well as radiation transmitted through the film 112 yields four measured values, one from each scan, that may be mathematically processed in a variety of ways to produce the initial three colors, red, green and blue, closest to the original scene.

The front signal records the radiation 222 reflected from the illumination source 216 in front of the film 112. The set of front signals for an image is called the front channel. The front channel principally, but not entirely, records the attenuation in the radiation from the source 216 due to the silver metal particles 234 in the top-most layer 246, which is the blue recording layer. There is also some attenuation of the front channel due to silver metal particles 236, 238 in the red and green layers 242, 244.

The back signal records the radiation 224 reflected from the illumination source 218 in back of the film 112. The set of back signals for an image is called the back channel. The back channel principally, but not entirely, records the attenuation in the radiation from the source 218 due to the silver metal particles 236 in the bottom-most layer 242, which is the red recording layer. Additionally, there is some attenuation of the back channel due to silver metal particles 234,238 in the blue and green layers 246, 244.

The front-through signal records the radiation 230 that is transmitted through the film 220 from the illumination source 218 in back of the film 112. The set of front-through signals for an image is called the front-through channel. Likewise, the back-through signal records the radiation 240 that is transmitted through the film 112 from the source 216 in front of the film 112. The set of back-through signals for an image is called the back-through channel. Both through channels record essentially the same image information since they both record the attenuation of the radiation 230, 240 due to the silver metal particles 234,236,238 in all three red, green, and blue recording layers 242, 244, 246 of the film 112.

Several image processing steps are required to convert the illumination source radiation information for each channel to the red, green, and blue values similar to those produced by conventional scanners for each spot on the film 220. These steps are required because the silver metal particles 234, 236, 238 that form during the development process are not spectrally unique in each of the film layers 242, 244, 246. These image processing steps are not performed when conventional scanners are used because the dyes which are formed with conventional chemical color processing scanners, once initial red, green and blue values are derived for each image, further processing of the red, green and blue values is usually done to produce images that more accurately reproduce the original scene and that are pleasing to the human eye.

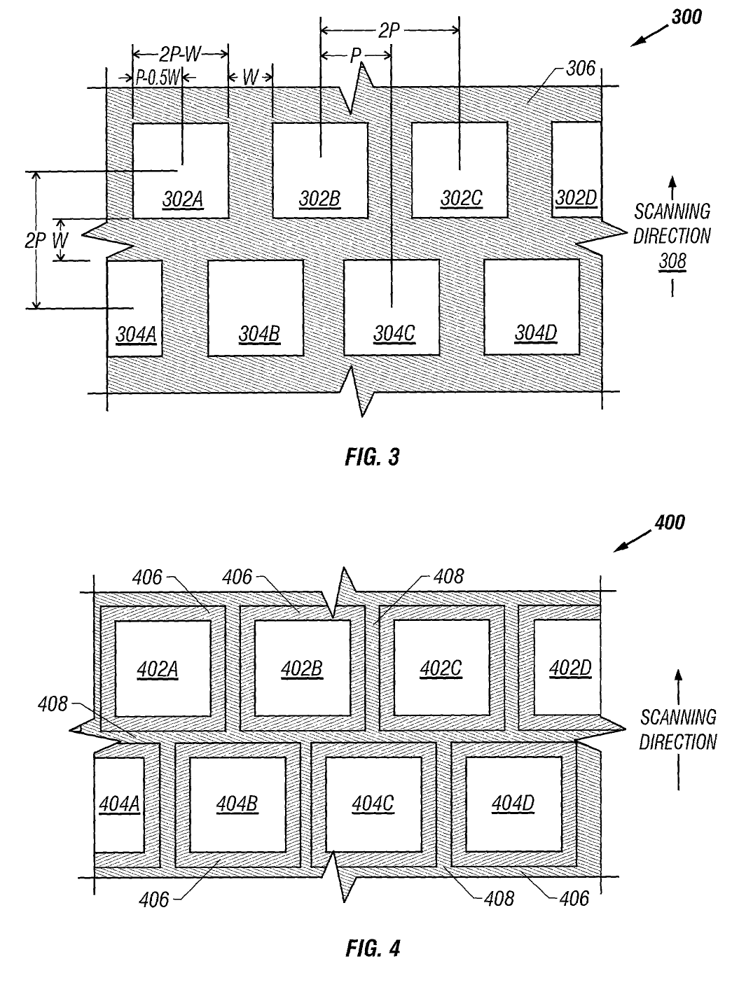

FIG. 3 shows a portion of an image sensor 300 that may be used in accordance with one embodiment of the present invention. The image sensor 300 comprises a number of imaging elements 302a, 302b, 302c, 302d, 304a, 304b, 304c, 304d separated by a non-imaging material 306. Imaging elements 302a, 302b, 302c and 302d form a portion of a first sensor row 302 and imaging elements 304a, 304b, 304c and 304d form a portion of a second sensor row 304. Accordingly, FIG. 3 only shows a portion of the first sensor row 302 and the second sensor row 304. In addition, FIG. 3 only shows a portion of imaging elements 302d and 304a.

Imaging elements 302a, 302b, 302c, 302d, 304a, 304b, 304c and 304d maybe any component that converts light into an electrical charge; for example, in one embodiment, the imaging elements 302, 304 comprises a charge-coupled device (“CCD”). The non-imaging material 306 may be a substrate material or any added material to reduce diffusion between neighboring imaging elements 302a, 302b, 302c, 302d, 304a, 304b, 304c and 304d.

In one embodiment, the edges of imaging elements 302a, 302b, 302c, 302d, 304a, 304b, 304c, 304d are separated from each other by a distance of W in both the scanning direction 308 and down the first and second sensor rows 302 and 304. The distance W is preferably selected to be large enough so that the non-imaging material 306 can reduce diffusion between the neighboring imaging elements 302a, 302b, 302c, 302d, 304a, 304b, 304c and 304d, but less than the width of each imaging element 302a, 302b, 302c, 302d, 304a, 304b, 304c or 304d. For example, the distance W may be selected to be one-half the width of each imaging element 302a, 302b, 302c, 302d, 304a, 304b, 304c or 304d. Specifically, if each imaging element 302a, 302b, 302c, 302d, 304a, 304b, 304c or 304d has a width of 12 microns, the distance W would be 6 microns. The embodiment shown in FIG. 3, should produce a 25% increase in efficiency compared to conventional systems.

In another embodiment, imaging elements 302a, 302b, 302c and 302d are offset from imaging elements 304a, 304b, 304c and 304d by a distance P in the scanning direction 308. As shown, the distance P is approximately equal to the distance from the center of imaging element 302bto the center of the non-imaging material 306 between imaging elements 302b and 302c. In other words, imaging element 304c is aligned with the center of the non-imaging material 306 between imaging elements 302b and 302c. Accordingly, the centers of imaging elements 302a, 302b, 302c and 302d are separated from each other by a distance of 2P. Similarly, the centers of imaging elements 302a, 302b, 302c and 302d are separated from the centers of imaging elements 304a, 304b, 304c and 304d in the scanning direction 308 by a distance of 2P.

Diffusion between neighboring imaging elements 302a, 302b, 302c, 302d, 304a, 304b, 304c and 304d will increase as the wavelength of the image increases, such as near infrared light. Near infrared photons penetrate deeper into the silicon than the electric field created by one of the imaging elements, such as 302a. According to the prior art, when the near infrared photons generate electrons underneath the imaging element, the electrons diffuse randomly and sometimes end up in the wrong imaging element. As a result of this diffusion, the resulting image is blurred and the MTF response of the image sensor is reduced. The present invention reduces this problem by separating the imaging elements 302a, 302b, 302c, 302d, 304a, 304b, 304c and 304d with the non-imaging material 306 that reduces the probability that an uncaptured electron will end up in the wrong imaging element without affecting the probability that the uncaptured electron will end up in the correct imaging element. Separating the imaging elements 302a, 302b, 302c, 302d, 304a, 304b, 304c and 304d with the non-imaging material 306 also reduces the number of wayward electrons that end up in the wrong imaging element and thus improves image resolution and the MTF response of the image sensor. In addition, separating the imaging elements with the non-imaging material 306 allows a performance improvement with standard imaging elements. Using standard imaging elements improves sensor production yield because special imaging elements often have increased defect rates. Moreover, standard imaging elements generally produce less dark currents than special imaging elements having deep depletion regions.

The present invention allows the sensor sensitivity to be increased while increasing the Nyquist frequency. A down sampled image can be constructed at equivalent resolution to a 100% fill-factor sensor that has a better signal to noise ratio. The signal to noise ratio is better because the sensor random electronic noise level is lower due to the increased sensitivity caused by the offset of the imaging elements which results in a finer pitch than their rectangular spacing. Accordingly, the sampling frequency relative to the frequency contents of the imaging elements is increased, which means that less energy is above the Nyquist frequency. In addition, the image high frequency noise level is lower due to decreased aliasing of out of band image noise.

FIG. 4 shows a portion of an image sensor 400 in accordance with another embodiment of the present invention. The image sensor 400 has a number of imaging elements 402a, 402b, 402c, 402d, 404a, 404b, 404c, 404d separated by a non-imaging material 406 and structure 408. The non-imaging material 406 promotes recombination of diffused electrons into imaging elements 402a, 402b, 402c, 402d, 404a, 404b, 404c and 404d. Moreover, structure 408 is a trough or charge collecting implant material that prevents diffusion of electrons into neighboring imaging elements 402a, 402b, 402c, 402d, 404a, 404b, 404c and 404d. Otherwise, the description of FIG. 3 is applicable to FIG. 4.

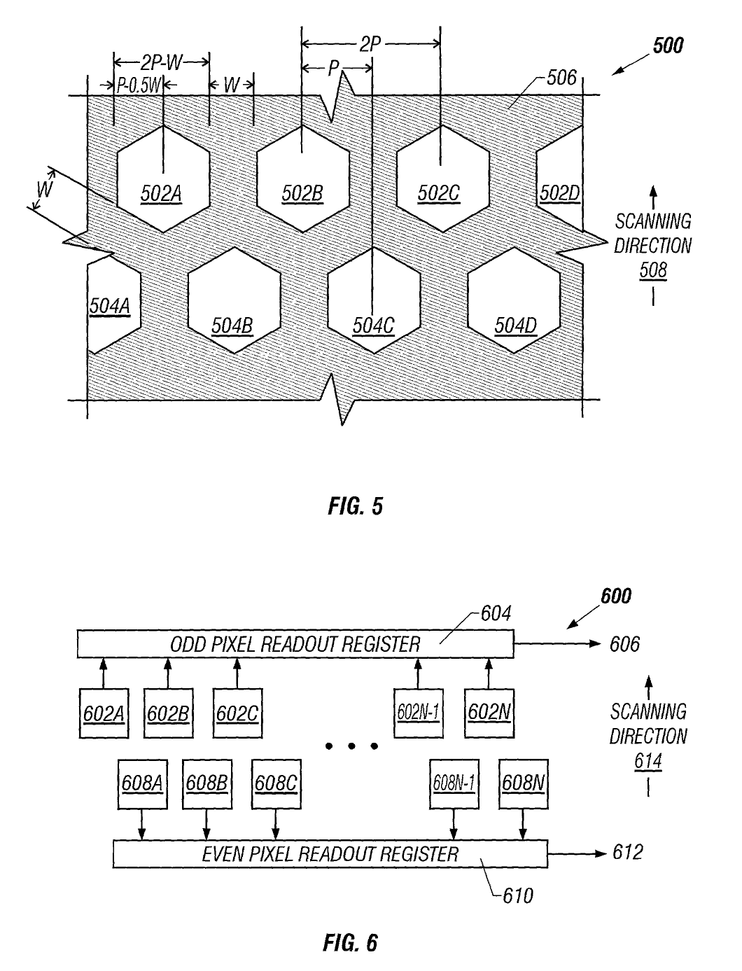

FIG. 5 shows a portion of an image sensor 500 in accordance with another embodiment of the present invention. The image sensor 500 comprises a number of imaging elements 502a, 502b, 502c, 502d, 504a, 504b, 504c, 504d separated by a non-imaging material 506. Imaging elements 502a, 502b, 502c and 502d form a portion of a first sensor row 502 and imaging elements 504a, 504b, 504c and 504d form a portion of a second sensor row 504.

Imaging elements 502a, 502b, 502c, 502d, 504a, 504b, 504c, 504d are shown to be polygonal-shaped rather than square-shaped as shown in FIG. 3. Imaging elements 502a, 502b, 502c and 502d are offset from imaging elements 504a, 504b, 504c and 504d by a distance P in the scanning direction 508. In this embodiment, the distance P is approximately equal to the distance from the center of imaging element 502b to the center of the non-imaging material 506 between imaging elements 502b and 502c. In other words, imaging element 504c is aligned with the center of the non-imaging material 506 between imaging elements 502b and 502c. Accordingly, the centers of imaging elements 502a, 502b, 502c and 502d are separated from each other by a distance of 2P.

The edges of imaging elements 502a, 502b, 502c, 502d, 504a, 504b, 504c, 504d are separated from each other by a distance of W. The distance W is preferably selected to be large enough so that the non-imaging material 506 can reduce diffusion between the neighboring imaging elements 502a, 502b, 502c, 502d, 504a, 504b, 504c and 504d, but less than the width of each imaging element 502a, 502b, 502c, 502d, 504a, 504b, 504c or 504d. Although the imaging elements 502a, 502b, 502c, 502d, 504a, 504b, 504c or 504d are illustrated as hexagons, but could also be circular-shaped, or any other suitable shape.

FIG. 6, is a block diagram of a image sensor circuit 600 in accordance with the present invention. The image sensor 600 has a odd sensor row 602 containing n imaging elements 602a, 602b, 602c, 602d, . . . 602n. An odd pixel readout register 604 is coupled to the odd sensor row 602 for reading an image signal from each of the imaging elements 602a, 602b, 602c, 602d, . . . 602n and converting the image signals to an odd pixel image 606. Similarly, the image sensor 600 has an even sensor row 608 containing n imaging elements 608a, 608b, 608c, 608d, . . . 608n. An even pixel readout register 610 is coupled to the even sensor row 608 for reading an image signal from each of the imaging elements 608a, 608b, 608c, 608d, . . . 608n and converting the image signals into an even pixel image 612.

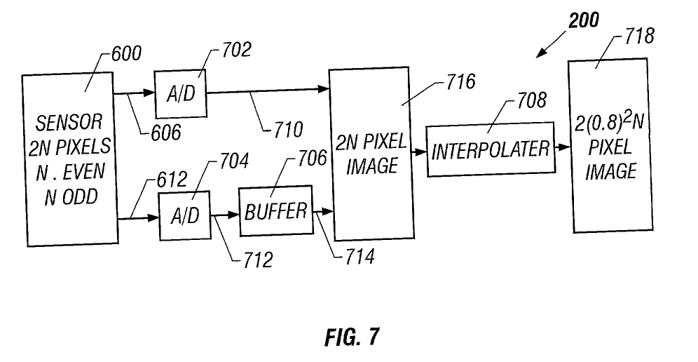

As will be described in reference FIG. 7, the odd pixel image 606 and even pixel image 612 will be converted into an odd pixel digital image and an even pixel digital image. The odd pixel digital image will then be combined with the even pixel digital image. The odd pixel digital image will then be combined with the even pixel digital image to form a digital output image 712 (FIG. 7). Thus, imaging elements that will be adjacent in the digital output image 712 (FIG. 7) are offset specially in the scanned direction 614. In other words, the digital output image would be the output from imaging elements 602a, 608a, 602b, 608b, 602c, 608c, . . . 602n, 608n and would be 2n pixels in length. In particular, as the image is scanned in the scanning direction 614, the image goes by an even set of pixels 608a, 608b, 608c, . . . 608n and then by an odd set of pixels 602a, 602b, 602c, . . . 602n.

FIG. 7, a block diagram of an image processing circuit 700 in accordance with the present invention. The image processing circuit 700 includes a sensor 600 having 2N sensors (N even sensors and N odd sensors), two analog to digital converters (A/D) 702, 704, a buffer 706 and an interpolater 708. The odd pixel image 606 is converted to a odd pixel digital image 710 by A/D converter 702. The even pixel image 612 is converted to a even pixel digital image 712 by A/D converter 704. The buffer 706 delays the even pixel digital image 712 for a time period corresponding to the distance between the odd sensor row 602 (FIG. 6) and the even sensor row 608 (FIG. 6). Thus, the time period is based on the scanning rate. The odd pixel digital image 710 and the buffered even pixel digital image 714 produce a 2N pixel digital image 716. The interpolater 708 takes the 2N pixel digital image 716 and creates a 2(0.8)2N pixel image 718.

The present invention is useful in any linear image sensor that is to be used in a digital scanning application. The invention is most advantageous under conditions where diffusion is a problem, such as near infrared, where the scanned image has content above the desired final image Nyquist frequency and where sensor sensitivity is an issue. Although preferred embodiments of the invention have been described in detail, it will be understood by those skilled in the art that various modifications can be made therein without departing from the spirit and scope of the invention as set forth in the appended claims.

What is claimed is:

1. An image sensor comprising:
a first sensor row formed by two or more imaging elements separated from each other by a non-imaging material; and
a second sensor row formed by two or more imaging elements separated from each other by the non-imaging material, the imaging elements in the second sensor row separated and offset from the imaging elements in the first sensor row by the non-imaging material.

2. The image sensor as recited in claim 1, wherein each imaging element comprises a photo-electric converting pixel.

3. The image sensor as recited in claim 1, wherein each imaging element comprises a pixel of a charge-coupled device.

4. The image sensor as recited in claim 1, wherein each imaging element is substantially square-shaped.

5. The image sensor as recited in claim 1, wherein each imaging element is polygonal-shaped.

6. The image sensor as recited in claim 1, wherein the non-imaging material reduces diffusion between neighboring imaging elements.

7. The image sensor as recited in claim 1, wherein the non-imaging material promotes recombination of diffused electrons into the imaging elements.

8. The image sensor as recited in claim 1, wherein the non-imaging material comprises a structure to prevent diffusion between neighboring imaging elements.

9. The image sensor as recited in claim 1, wherein each imaging element is separated from neighboring imaging elements within the same sensor row by a distance of approximately one-half the width of the imaging element.

10. The image sensor as recited in claim 1, wherein each imaging element in the first sensor row is separated from neighboring imaging elements in the second sensor row by a distance of approximately one-half the width of the imaging element.

11. The image sensor as recited in claim 1, wherein the imaging elements in the first sensor row are offset from the imaging elements in the second sensor row by a distance of approximately one-half the sum of the width of the imaging element and the non-imaging material between adjacent imaging elements.

12. The image sensor as recited in claim 1, further comprising:
a first readout register coupled to the first sensor row for reading a first image signal from each of the imaging elements in the first sensor row and converting the first image signals into a first digital image; and
a second readout register coupled to the second sensor row for reading a second image signal from each of the imaging elements in the second sensor row and converting the second image signals into a second digital image.

13. The image sensor as recited in claim 12, further comprising:
a delay circuit coupled to the second readout register to delay the second digital image for a time period corresponding to the distance between the first sensor row and the second sensor row; and
an adder circuit coupled to the first readout register and the delay circuit to produce an digital output image by adding the first digital image to the second digital image.

14. The image sensor as recited in claim 13, further comprising a buffer coupled to the adder circuit to store one or more of the digital output images.

15. An image sensor comprising:
a first sensor row formed by two or more imaging elements separated from each other by a non-imaging material that reduces diffusion between neighboring imaging elements, the non-imaging material having a width of approximately one-half the width of the imaging element;
a second sensor row formed by two or more imaging elements separated from each other by the non-imaging material having a width of approximately one-half the width of the imaging element;
the imaging elements in the first sensor row separated from the neighboring imaging elements in the second sensor row by the non-imaging material having a width of approximately one-half the width of the imaging element; and
the imaging elements in the first sensor row offset from the imaging elements in the second sensor row by a distance of approximately one-half times the sum of the width of the imaging element and the non-imaging material between adjacent imaging elements.

16. The image sensor as recited in claim 15, wherein each imaging element comprises a photo-electric converting pixel.

17. The image sensor as recited in claim 15, wherein each imaging element is substantially square-shaped.

18. The image sensor as recited in claim 15, wherein each imaging element is polygonal-shaped.

19. The image sensor as recited in claim 15, wherein the non-imaging material promotes recombination of diffused electrons into the imaging elements.

20. The image sensor as recited in claim 15, wherein the non-imaging material includes a structure to prevent diffusion between neighboring imaging elements.

21. An imaging system comprising:
at least one light source operable to illuminate a photographic media; and
at least one image sensor operable to detect light from the photographic media, the image sensor comprising a first sensor row formed by two or more imaging elements separated from each other by a non-imaging material and a second sensor row formed by two or more imaging elements separated from each other by the non-imaging material, the imaging elements in the second sensor row separated and offset from the imaging elements in the first sensor row by the non-imaging material.
